(19) United States
(12) Patent Application Publication
(10) Pub. No.: US 2010/0308304 A1
(43) Pub. Date: Dec. 9, 2010

(54) ELECTRONIC SHORT CHANNEL DEVICE COMPRISING AN ORGANIC SEMICONDUCTOR FORMULATION

(76) Inventors: Simon Dominic Ogier, Bedale (GB); Janos Veres, Pittsford, NY (US); Munther Zeidan, Amman (GB)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 12/161,279

(22) PCT Filed: Dec. 20, 2006
(86) PCT No.: PCT/EP06/12300

§ 371 Date: Aug. 30, 2010

(30) Foreign Application Priority Data
Jan. 21, 2006 (EP) 06001282.0

(51) Int. Cl. H01L 51/30; H01L 51/05; H01L 51/40; H01L 51/46; H01L 51/54

(52) U.S. Cl. 257/40; 438/99; 257/E51.002; 257/E51.005; 257/E51.024

(57) ABSTRACT

The invention relates to an improved electronic device, like an organic field emission transistor (OFET), which has a short source to drain channel length and contains an organic semiconducting formulation comprising a semiconducting binder.

### FIELD OF THE INVENTION

The invention relates to an improved electronic device, like an organic field emission transistor (OFET), which has a short source to drain channel length and contains an organic semiconducting formulation comprising a semiconducting binder.

### BACKGROUND AND PRIOR ART

In recent years, there has been development of organic semiconducting (OSC) materials in order to produce more versatile, lower cost electronic devices. Such materials find application in a wide range of devices or apparatus, including organic field effect transistors (OFETs), organic light emitting diodes (OLEDs), photodetectors, organic photovoltaic (OPV) cells, sensors, memory elements and logic circuits to name just a few. The organic semiconducting materials are typically present in the electronic device in the form of a thin layer, for example less than 1 micron thick.

Improved charge mobility is one goal of new electronic devices. Another goal is improved stability, film uniformity and integrity of the OSC layer.

One way potentially to improve OSC layer stability and integrity in devices is to include the OSC component in an organic binder, as disclosed in WO 2005/055248 A2. Typically one would expect reduction of charge mobility and disruption of the molecular order in the semiconducting layer, due to its dilution in the binder. However, the disclosure of WO 2005/055248 A2 shows that a formulation comprising an OSC material and a binder still shows a surprisingly high charge carrier mobility, which is comparable to that observed for highly ordered crystalline layers of OSC compounds. Besides, a formulation as taught in WO 20051055248 A2 has a better processibility than conventional OSC materials.

The inventors of the present invention have found that further improvements can be made by the choice of the binder material. The inventors found that in some cases the semiconductor and the binder may exhibit some degree of phase separation, especially at the electrode contacts. This phase separation may become a problem if a thin insulating binder layer covers the source and drain. It was also surprisingly found that this problem is more apparent in case of small dimension semiconducting devices with short channel lengths.

It was an aim of the present invention to reduce or overcome the disadvantages in OSC layers of prior art, to provide improved electronic devices, to provide improved OSC materials and components to be used in such devices, and to provide methods for their manufacture. The device should exhibit improved stability, high film uniformity and high integrity of the OSC layer, the materials should have a high charge mobility and good processibility, and the method should enable easy and time- and cost-effective device production especially at large scale. Other aims of the present invention are immediately evident to the expert from the following detailed description.

It has been found that these aims can be achieved by providing devices, OSC materials, formulations and methods as claimed in the present invention.

In particular, the inventors of the present invention have surprisingly found that disadvantages detected in OSC layers of prior art, comprising an OSC compound and an organic binder, can be overcome by using a semiconducting binder. The inventors of the present invention have also surprisingly found that semiconducting binders offer significant advantages especially in electronic devices having short channel lengths. The advantages by using a semiconducting binder become particularly significant when the source-drain distance is less than 50 microns, in particular 20 microns and especially less than 10 microns. It is believed that the contact properties of the device are improved, because the semiconducting binder provides a much more effective path for carrier transport between the contacts and the polycrystalline semiconductor channel than an insulating binder, although the distance to be overcome may only be a few tens of nms.

Interestingly, an inert binder does not inhibit transport in the polycrystalline blend layer itself. Evidence of this can be clearly seen from the high mobilities (often greater than 0.1 cm²V⁻¹s⁻¹) with both insulating and semiconducting binders for long channel devices as shown e.g. in WO 2005/055248 A2. This is attributed to a continuous path being formed through the crystallites. However, in short channel devices mobility problems were observed when using insulating binders.

An alternative solution to avoid preferential wetting of contacts by the binder polymer is to adjust the surface energy of the contacts. However, this is not easily done as the contacts also have to be ohmic and their workfunction should remain high. Instead, using a semiconducting binder as described in the present invention simplifies the contact optimisation.

The advantages achieved by the present invention were not disclosed or suggested by prior art. WO2005/055248 A2 discloses improved formulations of OSCs comprising a soluble polyacene and an organic binder resin having a permittivity between 2 and 3.3. It is also disclosed that a variety of resins can be used as long as their polarity is low, and that the organic binder may a be a semiconducting polymer. However, WO2005/055248 A2 does not disclose short channel devices, and teaches similar performance for OSC formulations when using either insulating or semiconducting binders.

### SUMMARY OF THE INVENTION

The invention relates to an electronic component or device comprising a gate electrode, a source electrode and a drain electrode, wherein the source and the drain electrode are separated by a specific distance, also referred to as “channel length”, and wherein the device further comprises an organic semiconducting (OSC) material that is provided between the source and drain electrode and comprises one or more OSC compounds and an organic binder, characterized in that the channel length L is ≦50 microns and the binder is a semiconducting binder.

The invention further relates to an OSC formulation comprising one or more OSC compounds and one or more organic semiconducting binders, or precursor(s) thereof, especially for use in a short channel OFET device as described above and below.

Based on the improvement achieved with short channel OFETs the inventive formulations may also be used to enhance contact properties in other devices. Said electronic component or devices include, without limitation, an organic field effect transistor (OFET), thin film transistor (TFT), component of integrated circuitry (IC), radio frequency identification (RFID) tag, photodetector, sensor, logic circuit, memory element, capacitor, organic photovoltaic (OPV) cell, charge injection layer and Schottky diodes.

### BRIEF DESCRIPTION OF THE DRAWINGS

FIG. 1 illustrates the calculation of field effect mobility from saturated regime of an OFET.

FIG. 2 shows the saturated mobility as a function of channel length for two OSC formulations according to example 1.

FIG. 3 exemplarily depicts a short channel OFET device according to the present invention.

FIG. 4 shows the transfer characteristics (current and mobility) of an OFET device according to example 2.

FIG. 5 shows the mobility as a function of channel length for an OSC formulation according to example 2.

### DETAILED DESCRIPTION OF THE INVENTION

The electronic device according to the present invention is characterized by a short channel length (i.e. distance between source and drain electrode). The channel length is ≦50 microns, preferably ≦20 microns, very preferably ≦10 microns. The channel length is typically greater than 0.05 microns.

The OSC material can be a small molecule compound or a mixture of two or more small molecule compounds. Especially preferred are small molecule OSC compounds with charge carrier mobilities ≧10⁻³ cm²V⁻¹s⁻¹, very preferably ≧10⁻² cm²V⁻¹s⁻¹, most preferably ≧10⁻¹ cm²V⁻¹s⁻¹, and preferably ≦50 cm²V⁻¹s⁻¹. The mobility can be determined on drop cast layers in an FET configuration. The molecular weight of the OSC compound is preferably between 300 and 10,000, more preferably 500 and 5,000, even more preferably 600 and 2,000. The small molecule OSC is preferably chosen such that it exhibits a high tendency to crystallise when solution coated.

Suitable and preferred small molecule OSC materials include, without limitation, oligo- and polyacenes as described for example in WO 2005/055248 A2 and EP 1 262 469 A1, unsymmetric polyacenes as described in international patent application WO 2006/119853 A1 or oligomeric acenes as described in international patent application WO 2006/125504 A1.

Particularly preferred OSC materials are soluble polyacenes of the following formulae

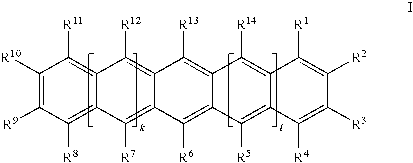

wherein
k is 0 or 1,
l is 0 or 1,
R¹⁻¹⁴ denote, in case of multiple occurrence independently of one another, identical or different groups selected from H, halogen, —CN, —NC, —NCO, —NCS, —OCN, —SCN, —C(═O)NR⁰R⁰⁰, —C(═O)X, —C(═O)R⁰, —NH₂, —NR⁰R⁰, —SH, —SR⁰, —SO₃H, —SO₂R⁰, —OH, —NO₂, —CF₃, —SF₅, optionally substituted silyl, or carbyl or hydrocarbyl with 1 to 40 C atoms that is optionally substituted and optionally comprises one or more hetero atoms,
X is halogen,
R⁰ and R⁰⁰ are independently of each other H or an optionally substituted carbyl or hydrocarbyl group optionally comprising one or more hetero atoms,
optionally two or more of the substituents R¹-R¹⁴, which are located on adjacent ring positions of the polyacene, constitute a further saturated, unsaturated or aromatic ring system having 4 to 40 C atoms, which is monocyclic or polycyclic, is fused to the polyacene, is optionally intervened by one or more groups selected from —O—, —S— and —N(R⁰)—, and is optionally substituted by one or more identical or different groups R¹,
optionally one or more of the carbon atoms in the polyacene skeleton or in the rings formed by R¹⁻¹⁴ are replaced by a heteroatom selected from N, P, As, O, S, Se and Te.

Unless stated otherwise, groups like R¹, R² etc., or indices like k etc., in case of multiple occurrence are selected independently from each other, and may be identical or different from each other. Thus, several different groups might be represented by a single label like for example ‘R⁵’.

The terms ‘alkyl’, ‘aryl’ etc. also include multivalent species, for example alkylene, arylene etc. The term ‘aryl’ or ‘arylene’ means an aromatic hydrocarbon group or a group derived from an aromatic hydrocarbon group. The term ‘heteroaryl’ or ‘heteroarylene’ means an ‘aryl’ or ‘arylene’ group comprising one or more hetero atoms.

The term ‘carbyl group’ as used above and below denotes any monovalent or multivalent organic radical moiety which comprises at least one carbon atom either without any non-carbon atoms (like for example —C≡C—), or optionally combined with at least one non-carbon atom such as N, O, S, P, Si, Se, As, Te or Ge (for example carbonyl etc.). The terms ‘hydrocarbon group’, and ‘hydrocarbyl group’ denote a carbyl group that does additionally contain one or more H atoms and optionally contains or more hetero atoms like for example N, O, S, P, Si, Se, As, Te or Ge.

A carbyl or hydrocarbyl group comprising a chain of 3 or more C atoms may also be linear, branched and/or cyclic, including spiro and/or fused rings.

Preferred carbyl and hydrocarbyl groups include alkyl, alkoxy, alkylcarbonyl, alkoxycarbonyl, alkylcarbonyloxy and alkoxycarbonyloxy, each of which is optionally substituted and has 1 to 40, preferably 1 to 25, very preferably 1 to 18 C atoms, furthermore optionally substituted aryl, aryl derivative or aryloxy having 6 to 40, preferably 6 to 25 C atoms, furthermore alkylaryloxy, arylcarbonyl, aryloxycarbonyl, arylcarbonyloxy and aryloxycarbonyloxy, each of which is optionally substituted and has 6 to 40, preferably 7 to 40, very preferably 7 to 25 C atoms.

The carbyl or hydrocarbyl group may be a saturated or unsaturated acyclic group, or a saturated or unsaturated cyclic group. Unsaturated acyclic or cyclic groups are preferred, especially alkenyl and alkynyl groups (especially ethynyl). Where the C₁-C₄₀ carbyl or hydrocarbyl group is acyclic, the group may be linear or branched. The C₁-C₄₀ carbyl or hydrocarbyl group includes for example: a C₁-C₄₀ alkyl group, a C₂-C₄₀ alkenyl group, a C₂-C₄₀ alkynyl group, a C₃-C₄₀ allyl group, a C₄-C₄₀ alkyldienyl group, a C₄-C₄₀ polyenyl group, a C₆-C₁₈ aryl group, a C₆-C₄₀ alkylaryl group, a C₆-C₄₀ arylalkyl group, a C₄-C₄₀ cycloalkyl group, a C₄-C₄₀ cycloalkenyl group, and the like. Preferred among the foregoing groups are a C₁-C₂₀ alkyl group, a C₂-C₂₀ alkenyl group, a C₂-C₂₀ alkynyl group, a C₃-C₂₀ allyl group, a C₄-C₂₀ alkyldienyl group, a C₆-C₁₂ aryl group and a C₄-C₂₀ polyenyl group, respectively; more preferred are a C₁-C₁₀ alkyl group, a C₂-C₁₀ alkenyl group, a C₂-C₁₀ alkynyl group (especially ethynyl), a C₃-C₁₀ allyl group, a C₄-C₁₀ alkyldienyl group, a C₆-C₁₂ aryl group and a C₄-C₁₀ polyenyl group, respectively; and most preferred is C₂₋₁₀ alkynyl.

Further preferred carbyl and hydrocarbyl groups include straight-chain, branched or cyclic alkyl with 1 to 40, preferably 1 to 25 C-atoms, which is unsubstituted, mono- or polysubstituted by F, Cl, Br, I or CN, and wherein one or more non-adjacent CH₂ groups are optionally replaced, in each case independently from one another, by —O—, —S—, —NH—, —NR⁰—, —SiR⁰R⁰⁰—, —CO—, —COO—, —OCO—, —O—CO—O—, —S—CO—, —CO—S—, —CO—NR⁰—, —NR⁰—CO—, —NR⁰—CO—NR⁰⁰—, —CX¹═CX²— or in such a manner that O and/or S atoms are not linked directly to one another, with R⁰ and R⁰⁰ having one of the meanings given as described above and below and X¹ and X² being independently of each other H, F, Cl or CN.

R⁰ and R⁰⁰ are preferably selected from H, straight-chain or branched alkyl with 1 to 12 C atoms or aryl with 6 to 12 C atoms.

Halogen is F, Cl, Br or I.

Preferred alkyl groups include, without limitation, methyl, ethyl, propyl, n-butyl, t-butyl, dodecanyl, trifluoromethyl, perfluoro-n-butyl, 2,2,2-trifluoroethyl, benzyl, 2-phenoxyethyl, etc.

Preferred alkynyl groups include, without limitation, ethynyl and propynyl.

Preferred aryl groups include, without limitation, phenyl, 2-tolyl, 3-tolyl, 4-tolyl, naphthyl, biphenyl, 4-phenoxyphenyl, 4-fluorophenyl, 3-carbomethoxyphenyl, 4-carbomethoxyphenyl, etc.

Preferred alkoxy groups include, without limitation, methoxy, ethoxy, 2-methoxyethoxy, t-butoxy, etc.

Preferred aryloxy groups include, without limitation, phenoxy, naphthoxy, phenylphenoxy, 4-methylphenoxy, etc.

Preferred amino groups include, without limitation, dimethylamino, methylamino, methylphenylamino, phenylamino, etc.

If two or more of the substituents R¹-R¹⁴ together with the polyacene form a ring system, this is preferably a 5-, 6- or 7-membered aromatic or heteroaromatic ring, preferably selected from pyridine, pyrimidine, thiophene, selenophene, thiazole, thiadiazole, oxazole and oxadiazole, especially preferably thiophene or pyridine.

The optional substituents on the ring groups and on the carbyl and hydrocarbyl groups for R¹ etc. include, without limitation, silyl, sulpha, sulphonyl, formyl, amino, imino, nitrilo, mercapto, cyano, nitro, halogen, C₁₋₁₂ alkyl, C₆₋₁₂ aryl, C₁₋₁₂ alkoxy, hydroxy and/or combinations thereof. These optional groups may comprise all chemically possible combinations in the same group and/or a plurality (preferably two) of the aforementioned groups (for example amino and sulphonyl if directly attached to each other represent a sulphamoyl radical).

Preferred substituents include, without limitation, F, Cl, Br, I, —CN, —NO₂, —NCO, —NCS, —OCN, —SCN, —C(═O)NR⁰R⁰⁰, —C(═O)X, —C(═O)R⁰, —NR⁰R⁰⁰, —OH, —SF₅, wherein R⁰, R⁰⁰ and X are as defined above, optionally substituted silyl, aryl with 1 to 12, preferably 1 to 6 C atoms, and straight chain or branched alkyl, alkoxy, alkylcarbonyl, alkoxycarbonyl, alkylcarbonlyoxy or alkoxycarbonyloxy with 1 to 12, preferably 1 to 6 C atoms, wherein one or more H atoms are optionally replaced by F or Cl. Examples for these preferred substituents are F, Cl, CH₃, C₂H₅, C(CH₃)₃, CH(CH₃)₂, CH₂CH(CH₃)C₂H₅OCH₃, OC₂H₅, COCH₃, COC₂H₅, COOCH₃, COOC₂H₅, CF₃, OCF₃, OCHF₂ and OC₂F₅.

Very preferred optional substituents comprise optionally substituted silyl, amino, F, Cl, CH₃, C₂H₅, C(CH₃)₃, CH(CH₃)₂ and CH₂CH(CH₃)C₂H₅.

The silyl group is optionally substituted and is preferably selected of the formula —SiR′R″R′″. Therein, each of R′, R″ and R′″ are identical or different groups selected from H, a C₁-C₄₀-alkyl group, preferably C₁-C₄-alkyl, most preferably methyl, ethyl, n-propyl or isopropyl, a C₆-C₄₀-aryl group, preferably phenyl, a C₆-C₄₀-arylalkyl group, a C₁-C₄₀-alkoxy group, or a C₆-C₄₀-arylalkyloxy group, wherein all these groups are optionally substituted for example with one or more halogen atoms. Preferably, R′, R″ and R′″ are each independently selected from optionally substituted C₁₋₁₀-alkyl, more preferably C₁₋₄-alkyl, most preferably C₁₋₃-alkyl, for example isopropyl, and optionally substituted C₆₋₁₀-aryl, preferably phenyl. Further preferred is a silyl group of formula —SiR′R″″ wherein R″″ forms a cyclic silyl alkyl group together with the Si atom, preferably having 1 to 8 C atoms.

In one preferred embodiment of the silyl group, R′, R″ and R′″ are identical groups, for example identical, optionally substituted, alkyl groups, as in triisopropylsilyl. Very preferably the groups R′, R″ and R′″ are identical, optionally substituted C₁₋₁₀, more preferably C₁₋₄, most preferably C₁₋₃ alkyl groups. A preferred alkyl group in this case is isopropyl.

A silyl group of formula —SiR′R″R′″ or —SiR′R″″ as described above is a preferred optional substituent for the C₁-C₄₀-carbyl or hydrocarbyl group.

Preferred groups —SiR′R″R′” include, without limitation, trimethylsilyl, triethylsilyl, tripropylsilyl, dimethylethylsilyl, diethylmethylsilyl, dimethylpropylsilyl, dimethylisopropylsilyl, dipropylmethylsilyl, diisopropylmethylsilyl, dipropylethylsilyl, diisopropylethylsilyl, diethylisopropylsilyl, triisopropylsilyl, trimethoxysilyl, triethoxysilyl, triphenylsilyl, diphenylisopropylsilyl, diisopropylphenylsilyl, diphenylethylsilyl, diethyiphenylsilyl, diphenylmethylsilyl, triphenoxysilyl, dimethylmethoxysilyl, dimethylphenoxysilyl, methylmethoxyphenylsilyl, etc., wherein the alkyl, aryl or alkoxy group is optionally substituted.

Especially preferred are compounds of formula I wherein
R⁶ and R¹³ are —C≡C—SiR′R″R′″, with R′, R″ and R′″ being selected from optionally substituted C₁₋₁₀ alkyl and optionally substituted C₆₋₁₀ aryl, preferably straight-chain or branched C₁₋₆ alkyl or phenyl,
k=l=1,
R⁵, R⁷, R¹² and R¹⁴ are H,
at least one of R¹⁻⁴ and R⁸⁻¹¹ is different from H and is selected from straight-chain or branched C₁₋₆-alkyl or F,
l=0, and R² and R³ together with the polyacene form a heteroaromatic ring selected from pyridine, pyrimidine, thiophene, selenophene, thiazole, thiadiazole, oxazole and oxadiazole,
k=0, and R⁹ and R¹⁰ together with the polyacene form a heteroaromatic ring selected from pyridine, pyrimidine, thiophene, selenophene, thiazole, thiadiazole, oxazole and oxadiazole.

Examples of suitable and preferred compounds of formula I include, without limitation, the compounds listed below:

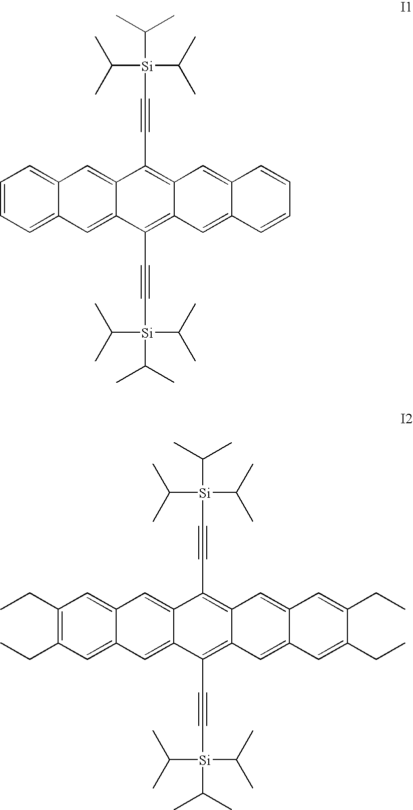

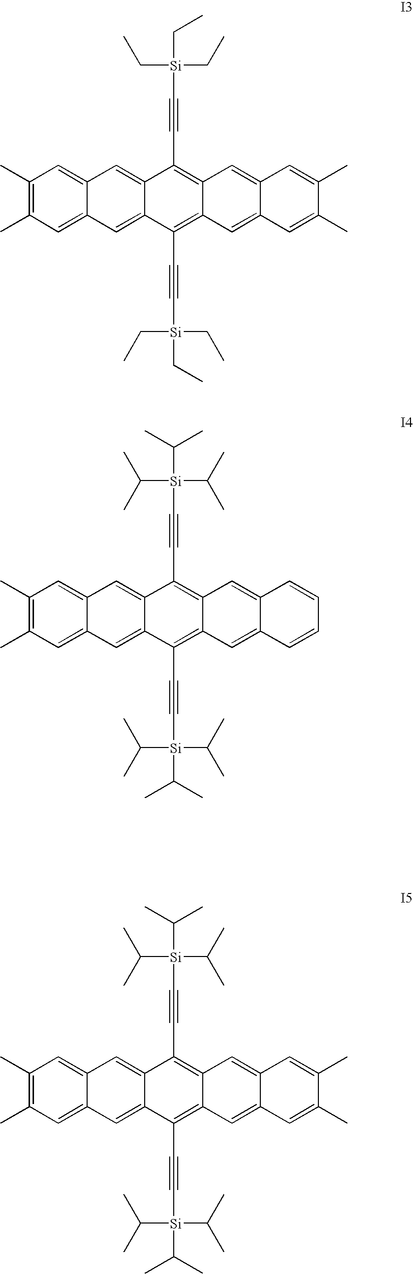

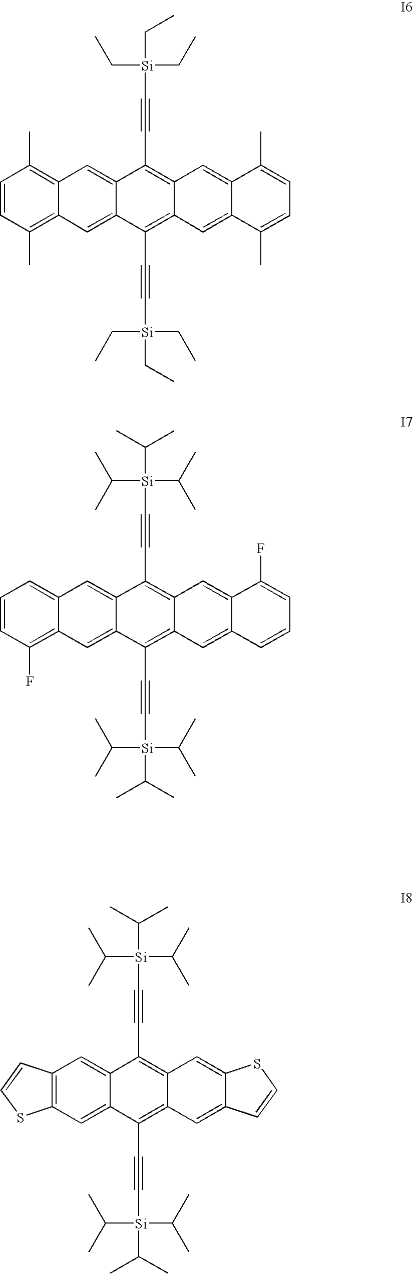

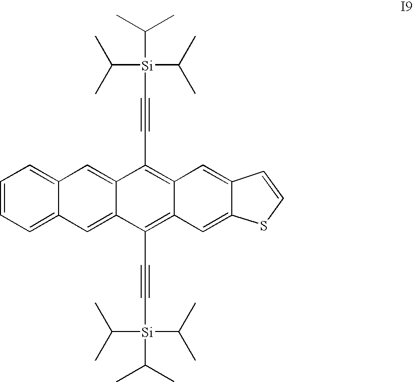

wherein the trialkylsilyl groups shown in these formulae may also be replaced by other trialkylsilyl groups, or by other groups —SiR′R″R′″ as defined above, and wherein the thiophene rings may also be substituted by one or more groups R¹ as defined above.

The semiconducting binder used in OSC formulations and electronic devices according to the present invention is selected from semiconducting polymers, or compositions or blends comprising at least one semiconducting polymer, or precursors thereof.

Suitable and preferred semiconducting binders include, without limitation, arylamine polymers as described in WO 99/32537 A1 and WO 00/78843 A1, semiconducting polymers as described in WO 2004/057688 A1, fluorene-arylamine copolymers as described in WO 99/54385 A1, indenofluorene polymers as described in WO 2004/041901 A1, Macromolecules 2000, 33(6), 2016-2020 and Advanced Materials, 2001, 13, 1096-1099, polysilane polymers as described by Dohmara et al., Phil. Mag. B. 1995, 71, 1069, polythiophenes as described in WO 2004/057688 A1, and polyarylamine-butadiene copolymers as described in JP 2005-101493 A1.

Generally, suitable and preferred binders are selected from polymers containing substantially conjugated repeat units, for example homopolymers or copolymers (including block copolymers) of the general formula II

A_{(c)}B_{(d)} . . . Z_{(z)} II

wherein A, B, . . . , Z in random polymers each represent a monomer unit and in block polymers each represent a block, and (c), (d), . . . (z) each represent the mole fraction of the respective monomer unit in the polymer, that is each (c), (d), . . . (z) is a value from 0 to 1 and the total of (c)+(d)+ . . . +(z)=1.

Examples of suitable and preferred monomer units or blocks A, B, . . . Z include those of formulae 1 to 8 given below. Therein m is as defined in formula 1a and, if >1, may also indicate a block unit instead of a single monomer unit.

1. Triarylamine units, preferably units of formula 1a (as disclosed in U.S. Pat. No. 6,630,566) or 1b

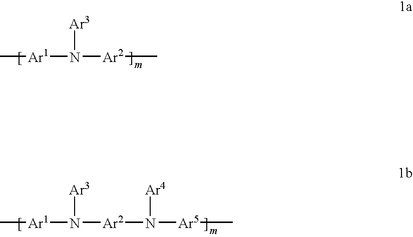

wherein
Ar¹⁻⁵ which may be the same or different, denote, independently if in different repeat units, an optionally substituted aromatic group that is mononuclear or polynuclear, and
m is 1 or an integer >1, preferably ≧10, more preferably ≧20.

In the context of Ar¹⁻⁵, a mononuclear aromatic group has only one aromatic ring, for example phenyl or phenylene. A polynuclear aromatic group has two or more aromatic rings which may be fused (for example napthyl or naphthylene), individually covalently linked (for example biphenyl) and/or a combination of both fused and individually linked aromatic rings. Preferably each of Ar¹⁻⁵ is an aromatic group which is substantially conjugated over substantially the whole group.

2. Fluorene units of formula 2

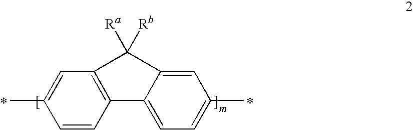

wherein
R^{a} and R^{b} are independently of each other selected from H, F, CN, NO₂, —N(R^{c})(R^{d}) or optionally substituted alkyl, alkoxy, thioalkyl, acyl, aryl,
R^{c} and R^{d} are independently or each other selected from H, optionally substituted alkyl, aryl, alkoxy or polyalkoxy or other substituents,

and wherein the asterisk (*) is any terminal or end capping group including H, and the alkyl and aryl groups are optionally fluorinated.

3. Heterocyclic units of formula 3

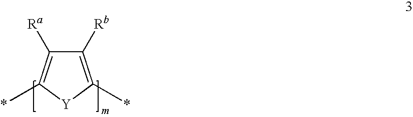

wherein
Y is Se, Te, O, S or —N(R^{e}), preferably O, S or —N(R^{e})—,
R^{e} is H, optionally substituted alkyl or aryl,
R^{a} and R^{b} are as defined in formula 2.

4. Units of formula 4

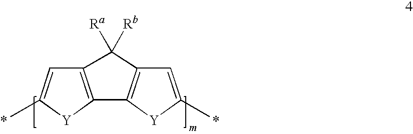

wherein R^{a}, R^{b} and Y are as defined in formulae 2 and 3.

5. Units of formula 5

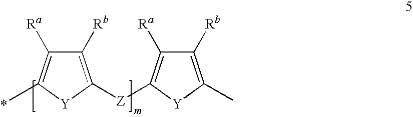

wherein R^{a}, R^{b} and Y are as defined in formulae 2 and 3,
z is —C(T¹)=C(T²)-, —C≡C—, —N(R^{f})—, —N═N—, (R^{f})=N—, —N═C(R^{f})—,
T¹ and T² independently of each other denote H, Cl, F, —CN or lower alkyl with 1 to 8 C atoms,
R^{f} is H or optionally substituted alkyl or aryl.

6. Spirobifluorene units of formula 6

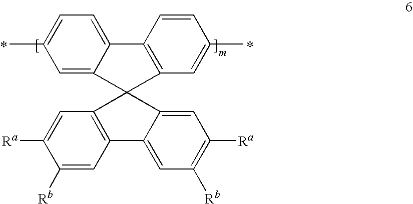

wherein R^{a} and R^{b} are as defined in formula 2.

7. Indenofluorene units of formula 7

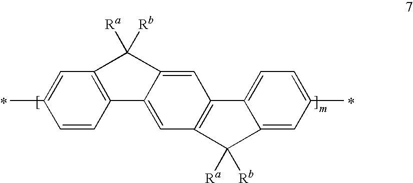

wherein R^{a} and R^{b} are as defined in formula 2.

8. Thieno[2,3-Nthiophene units of formula 8

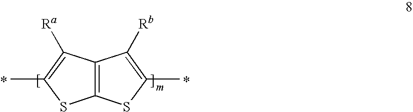

wherein R^{a} and R^{b} are as defined in formula 2.

9. Thieno[3,2-b]thiophene units of formula 9

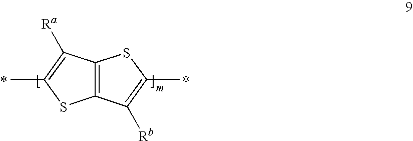

wherein R^{a} and R^{b} are as defined in formula 2.

In the case of the polymeric formulae described herein, such as formulae 1 to 9, the polymers may be terminated by any terminal group, that is any end-capping or leaving group, including H.

In the case of block copolymers, each monomer A, B, . . . Z may be a conjugated oligomer or polymer comprising a number m, for example 2 to 50, of the units of formulae 1-9.

Especially preferred semiconducting binders are PTAA and its copolymers, fluorene polymers and their copolymers with PTAA, polysilanes, in particular polyphenyltrimethyldisilane, and cis- and trans-indenofluorene polymers and their copolymers with PTAA having alkyl or aromatic substitution, in particular polymers of the following formulae:

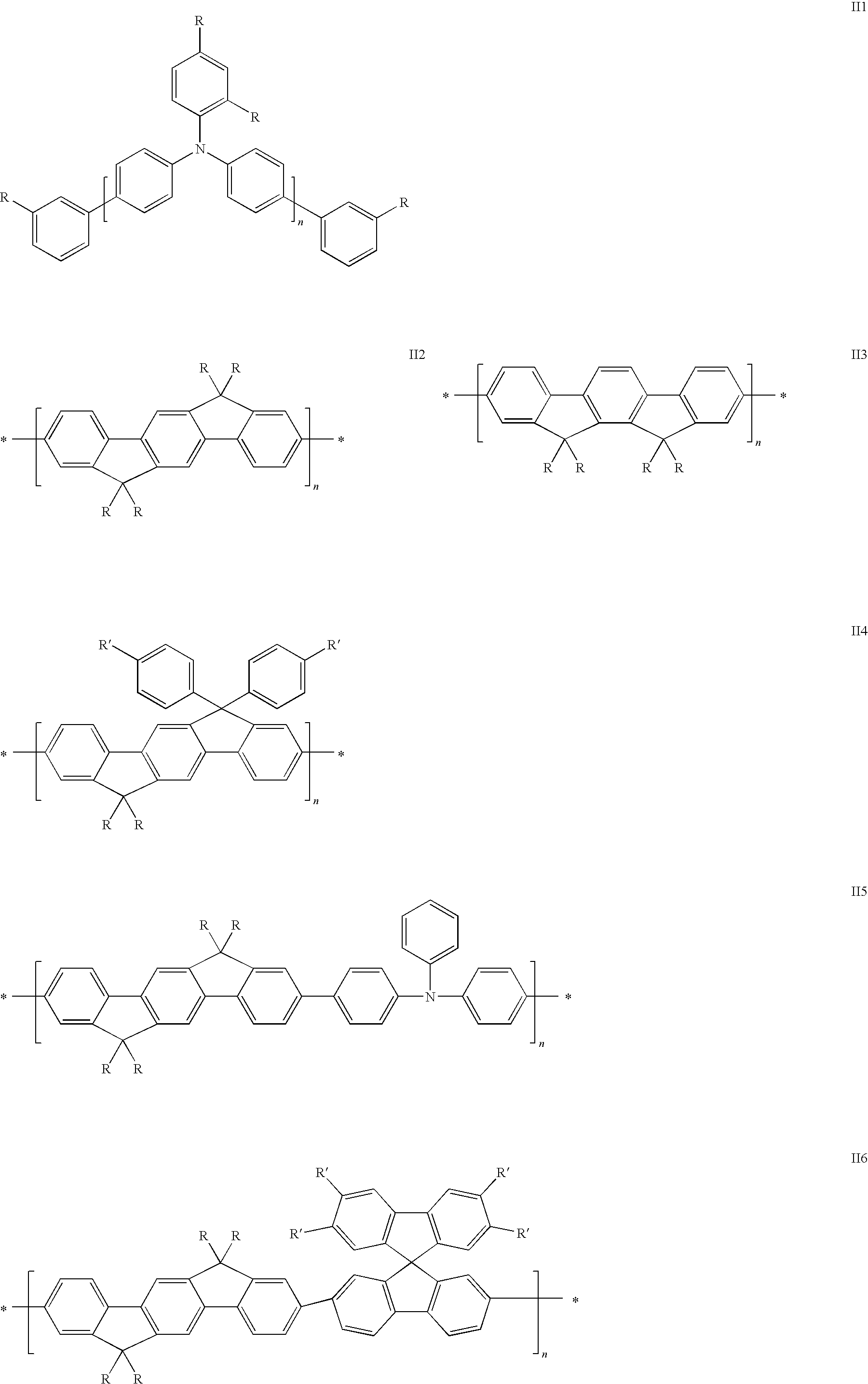

wherein
R has one of the meanings of R^{a} of formula 2, and preferably is straight-chain or branched alkyl or alkoxy with 1 to 20, preferably 1 to 12 C atoms, or aryl with 5 to 12 C atoms, preferably phenyl, that is optionally substituted,
R′ has one of the meanings of R, and
n is an integer>1.

Examples of typical and preferred polymers include, without limitation, the polymers listed below:

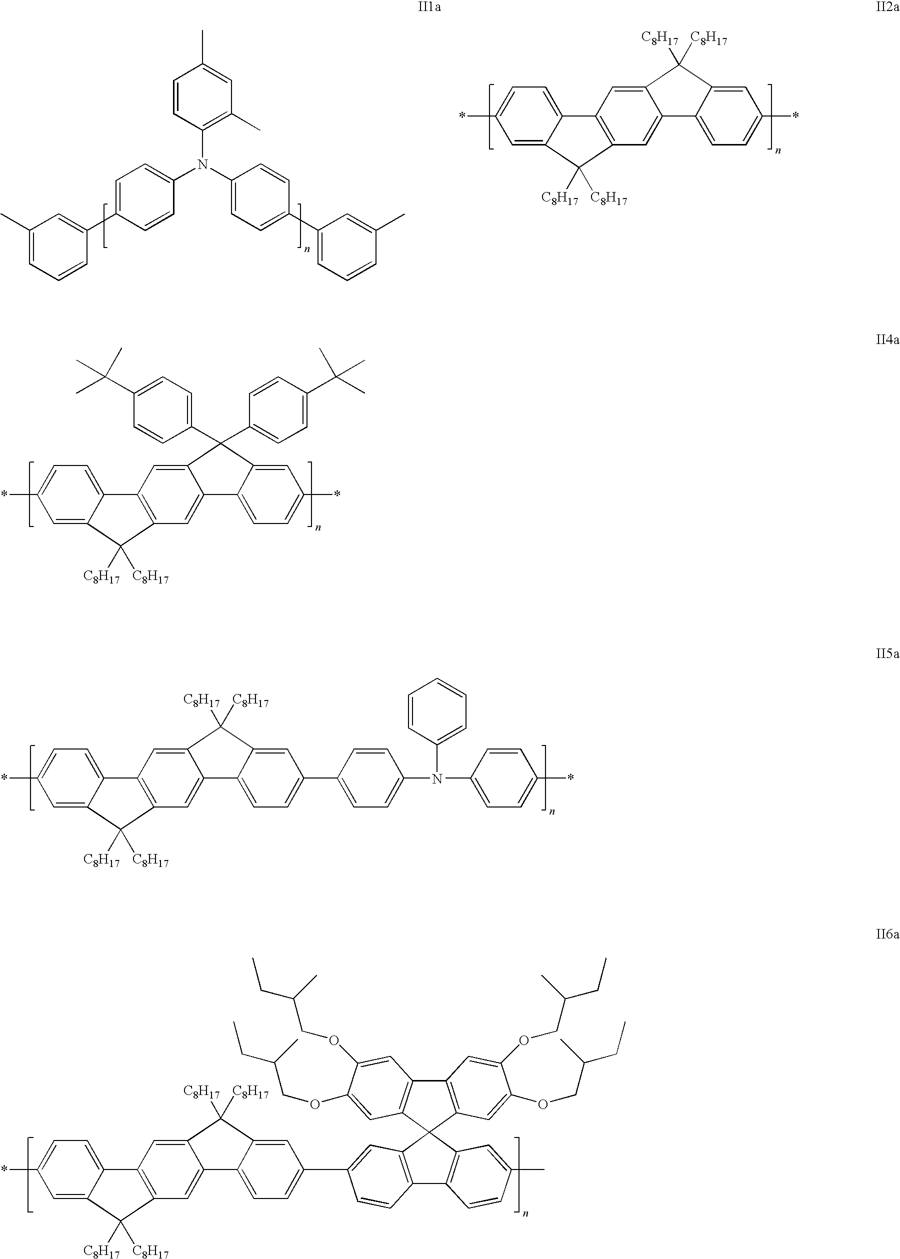

Preferably the semiconducting binder has a charge carrier mobility ≧10⁻³ cm²V⁻¹s⁻¹, more preferably ≧5×10⁻³ cm²V⁻¹s⁻¹, most preferably ≧10⁻² cm²V⁻¹s⁻¹, and preferably ≦1 cm²V⁻¹s⁻¹. Preferably the binder has an ionisation potential close to that of the crystalline small molecule OSC, most preferably within a range of +/−0.6 eV, even more preferably +/−0.4 eV of the ionisation potential of the small molecule OSC. The molecular weight of the binder polymer is preferably between 1000 and 10⁷, more preferably 10,000 and 10⁶, most preferably 20,000 and 500,000. Polyphenylene vinylene (PPV) polymers are less preferred, because they offer little or no benefit due to their low charge carrier mobility (typically <10⁻⁴ cm²V⁻¹s⁻¹). Similarly polyvinylcarbazole (PVK) is generally an effective binder, but is less preferred in the current invention because, due to its low mobility, it polymer is less efficient in improving contacts for short channel devices. Generally it is desirable that a polymer having a high charge carrier mobility is used as binder in the present invention. The semiconducting polymer is also preferably of low polarity, the permittivity being in the same range as defined above for insulating binders.

In order to adjust the rheological properties of the semiconducting binder/OSC small molecule composition, a small amount of inert binder may also be added. Suitable inert binders are described for example in WO 02/45184 A1. The inert binder content is preferably between 0.1% to 10% of the solid weight of the total composition after drying.

Selection of the most appropriate binder and formulation of the optimum binder to semiconductor ratio allows the morphology of the semiconducting layer to be controlled. Experiments have shown that morphologies ranging from amorphous through to crystalline can be obtained by variation of formulation parameters such as binder resin, solvent, concentration, deposition method, etc.

Important factors for the binder resin are as follows: the binder normally contains conjugated bonds and/or aromatic rings, the binder should preferably be capable of forming a flexible film, the binder should be soluble in commonly used solvents, the binder should have a suitable glass transition temperature and the permittivity of the binder should have little dependence on frequency.

For application of the semiconducting layer in p-channel FETs, it is desirable that the semiconducting binder should have a similar or higher ionisation potential than the OSC, otherwise the binder may form hole traps. In n-channel materials the semiconducting binder should have a similar or lower electron affinity than the n-type semiconductor to avoid electron trapping.

The formulation and the OSC layer according to the present invention may be prepared by a process which comprises:
(i) first mixing the OSC compound(s) and binder(s) or precursors thereof. Preferably the mixing comprises mixing the components together in a solvent or solvent mixture,
(ii) applying the solvent(s) containing the OSC compound(s) and binder(s) to a substrate; and optionally evaporating the solvent(s) to form a solid OSC layer according to the present invention,
(iii) and optionally removing the solid OSC layer from the substrate or the substrate from the solid layer.

In step (i) the solvent may be a single solvent, or the OSC compound(s) and the binder(s) may each be dissolved in a separate solvent followed by mixing the two resultant solutions to mix the compounds.

The binder may be formed in situ by mixing or dissolving the OSC compound(s) in a precursor of a binder, for example a liquid monomer, oligomer or crosslinkable polymer, optionally in the presence of a solvent, and depositing the mixture or solution, for example by dipping, spraying, painting or printing it, on a substrate to form a liquid layer and then curing the liquid monomer, oligomer or crosslinkable polymer, for example by exposure to radiation, heat or electron beams, to produce a solid layer. If a preformed binder is used it may be dissolved together with the compound of formula I in a suitable solvent, and the solution deposited for example by dipping, spraying, painting or printing it on a substrate to form a liquid layer and then removing the solvent to leave a solid layer. It will be appreciated that solvents are chosen which are able to dissolve both the binder and the OSC compound(s), and which upon evaporation from the solution blend give a coherent defect free layer.

Suitable solvents for the binder or the OSC compound can be determined by preparing a contour diagram for the material as described in ASTM Method D 3132 at the concentration at which the mixture will be employed. The material is added to a wide variety of solvents as described in the ASTM method.

A formulation according to the present invention may also comprise two or more OSC compounds and/or two or more binders or binder precursors, and the process described above may also be applied to such a formulation.

Examples of suitable and preferred organic solvents include, without limitation, dichloromethane, trichloromethane, monochlorobenzene, o-dichlorobenzene, tetrahydrofuran, anisole, morpholine, toluene, o-xylene, m-xylene, p-xylene, 1,4-dioxane, acetone, methylethylketone, 1,2-dichloroethane, 1,1,1-trichloroethane, 1,1,2,2-tetrachloroethane, ethyl acetate, n-butyl acetate, dimethylformamide, dimethylacetamide, dimethylsulfoxide, tetralin, decalin, indane and/or mixtures thereof.

After the appropriate mixing and ageing, solutions are evaluated as one of the following categories: complete solution, borderline solution or insoluble. The contour line is drawn to outline the solubility parameter-hydrogen bonding limits dividing solubility and insolubility. ‘Complete’ solvents falling within the solubility area can be chosen from literature values such as published in “Crowley, J. D., Teague, G. S. Jr and Lowe, J. W. Jr., Journal of Paint Technology, 38, No 496, 296 (1966)”. Solvent blends may also be used and can be identified as described in “Solvents, W. H. Ellis, Federation of Societies for Coatings Technology, p 9-10, 1986”. Such a procedure may lead to a blend of ‘non’ solvents that will dissolve both the binder and the compound of formula I, although it is desirable to have at least one true solvent in a blend.

Especially preferred solvents for use in the formulation according to the present invention, with semiconducting binders and mixtures thereof, are xylene(s), toluene, tetralin, chlorobenzene and o-dichlorobenzene.

The ratio of the OSC compound(s) to the binder in a formulation or layer according to the present invention is typically from 20:1 to 1:20 by weight, for example 1:1 by weight. In a preferred embodiment, the ratio of OSC compound(s) to binder is 10:1 or more, preferably 15:1 or more by weight. Ratios of up to 18:1 or 19:1 have also proven to be suitable.

In accordance with the present invention it has further been found that the level of the solids content in the organic semiconducting layer formulation is also a factor in achieving improved mobility values for electronic devices such as OFETs. The solids content of the formulation is commonly expressed as follows:

$$Solids content ( \% ) = \frac{a + b}{a + b + c} \times 100$$

wherein

a=mass of compound of formula I, b=mass of binder and c=mass of solvent.

The solids content of the formulation is preferably 0.1 to 10% by weight, more preferably 0.5 to 5% by weight.

It is desirable to generate small structures in modern microelectronics to reduce cost (more devices/unit area), and power consumption. Patterning of the layer of the invention may be carried out by photolithography, electron beam lithography or laser patterning.

Liquid coating of organic electronic devices such as field effect transistors is more desirable than vacuum deposition techniques. The formulations of the present invention enable the use of a number of liquid coating techniques. The organic semiconductor layer may be incorporated into the final device structure by, for example and without limitation, dip coating, spin coating, ink jet printing, letter-press printing, screen printing, doctor blade coating, roller printing, reverse-roller printing, offset lithography printing, flexographic printing, web printing, spray coating, brush coating or pad printing. The present invention is particularly suitable for use in spin coating the organic semiconductor layer into the final device structure.

Selected formulations of the present invention may be applied to prefabricated device substrates by ink jet printing or microdispensing. Preferably industrial piezoelectric print heads such as but not limited to those supplied by Aprion, Hitachi-Koki, InkJet Technology, On Target Technology, Picojet, Spectra, Trident, Xaar may be used to apply the organic semiconductor layer to a substrate. Additionally semi-industrial heads such as those manufactured by Brother, Epson, Konica, Seiko Instruments Toshiba TEC or single nozzle microdispensers such as those produced by Microdrop and Microfab may be used.

In order to be applied by ink jet printing or microdispensing, the mixture of the compound of formula I and the binder should be first dissolved in a suitable solvent. Solvents must fulfil the requirements stated above and must not have any detrimental effect on the chosen print head. Additionally, solvents should have boiling points >100° C., preferably >140° C. and more preferably >150° C. in order to prevent operability problems caused by the solution drying out inside the print head. Suitable solvents include substituted and non-substituted xylene derivatives, di-C₁₋₂-alkyl formamide, substituted and non-substituted anisoles and other phenol-ether derivatives, substituted heterocycles such as substituted pyridines, pyrazines, pyrimidines, pyrrolidinones, substituted and non-substituted N,N-di-C₁₋₂-alkylanilines and other fluorinated or chlorinated aromatics.

A preferred solvent for depositing a formulation according to the present invention by ink jet printing comprises a benzene derivative which has a benzene ring substituted by one or more substituents wherein the total number of carbon atoms among the one or more substituents is at least three. For example, the benzene derivative may be substituted with a propyl group or three methyl groups, in either case there being at least three carbon atoms in total. Such a solvent enables an ink jet fluid to be formed comprising the solvent with the binder and the OSC compound which reduces or prevents clogging of the jets and separation of the components during spraying. The solvent(s) may include those selected from the following list of examples: dodecylbenzene, 1-methyl-4-tert-butylbenzene, terpineol limonene, isodurene, terpinolene, cymene, diethylbenzene. The solvent may be a solvent mixture, that is a combination of two or more solvents, each solvent preferably having a boiling point >100° C., more preferably >140° C. Such solvent(s) also enhance film formation in the layer deposited and reduce defects in the layer.

The ink jet fluid (that is mixture of solvent, binder and semiconducting compound) preferably has a viscosity at 20° C. of 1-100 mPa·s, more preferably 1-50 mPa·s and most preferably 1-30 mPa·s.

The use of the binder in the present invention also allows the viscosity of the coating solution to be tuned to meet the requirements of the particular print head.

The semiconducting layer of the present invention is typically at most 1 micron (=1 μm) thick, although it may be thicker if required. The exact thickness of the layer will depend, for example, upon the requirements of the electronic device in which the layer is used. For use in an OFET or OLED, the layer thickness may typically be 500 nm or less.

The substrate used for preparing the OSC layer may include any underlying device layer, electrode or separate substrate such as silicon wafer, glass or polymer substrate for example.

In a particular embodiment of the present invention, the binder may be alignable, for example capable of forming a liquid crystalline phase. In that case the binder may assist alignment of the OSC compound(s), for example such that its long molecular axis is preferentially aligned along the direction of charge transport. Suitable processes for aligning the binder include those processes used to align polymeric organic semiconductors and are described in prior art, for example in WO 03/007397.

The OSC formulation according to the present invention can additionally comprise one or more further components like for example surface-active compounds, lubricating agents, wetting agents, dispersing agents, hydrophobing agents, adhesive agents, flow improvers, defoaming agents, deaerators, diluents, reactive or non-reactive diluents, auxiliaries, colourants, dyes, pigments or nanoparticles, furthermore, especially in case crosslinkable binders are used, catalysts, sensitizers, stabilizers, inhibitors, chain-transfer agents or co-reacting monomers.

The invention also relates to novel OSC materials, including OSC small molecules, semiconducting polymers or copolymers, and OSC formulations as described above and below, and to their use not only in short channel devices, but also in other electronic devices of the types described in this invention or in electroluminescent devices like organic light emitting diodes (OLEDs).

The invention further relates to an electronic device comprising the OSC layer. The electronic device may include, without limitation, an organic field effect transistor (OFET), organic light emitting diode (OLED), photodetector, sensor, logic circuit, memory element, capacitor or photovoltaic (PV) cell. For example, the active semiconductor channel between the drain and source in an OFET may comprise the layer of the invention. As another example, a charge (hole or electron) injection or transport layer in an OLED device may comprise the layer of the invention. The OSC formulations according to the present invention and OSC layers formed therefrom have particular utility in OFETs especially in relation to the preferred embodiments described herein.

An OFET device according to the present invention preferably comprises:
a source electrode,
a drain electrode,
a gate electrode,
an OSC layer as described above,
one or more gate insulator layers,
optionally a substrate,

The gate, source and drain electrodes and the insulating and semiconducting layer in the OFET device may be arranged in any sequence, provided that the source and drain electrode are separated from the gate electrode by the insulating layer, the gate electrode and the semiconductor layer both contact the insulating layer, and the source electrode and the drain electrode both contact the semiconducting layer.

The OFET device can be a top gate device or a bottom gate device. Suitable structures and manufacturing methods of an OFET device are known to the skilled in the art and are described in the literature, for example in WO 03/052841.

The gate insulator layer preferably comprises a fluoropolymer, like e.g. the commercially available Cytop 809M® or Cytop 107M® (from Asahi Glass). Preferably the gate insulator layer is deposited, e.g. by spin-coating, doctor blading, wire bar coating, spray or dip coating or other known methods, from a formulation comprising an insulator material and one or more solvents with one or more fluoro atoms (fluorosolvents), preferably a perfluorosolvent. A suitable perfluorosolvent is e.g. FC75® (available from Acros, catalogue number 12380). Other suitable fluoropolymers and fluorosolvents are known in prior art, like for example the perfluoropolymers Teflon AF® 1600 or 2400 (from DuPont) or Fluoropel® (from Cytonix) or the perfluorosolvent FC 43® (Acros, No. 12377).

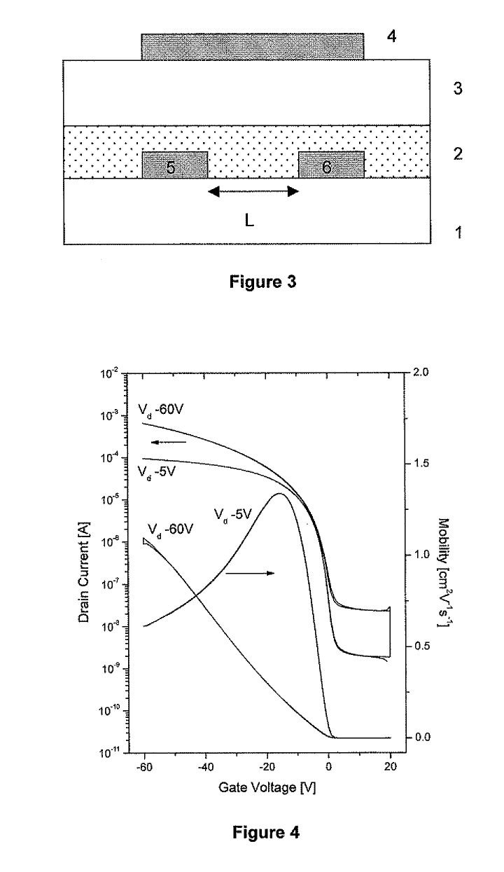

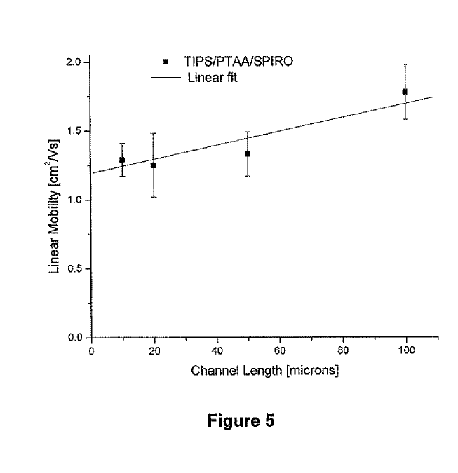

FIG. 3 exemplarily shows a cross-sectional view of a top gate OFET device according to a preferred embodiment of the present invention, comprising a substrate (1), a semiconductor layer (2), a gate dielectric (insulator) layer (3), a gate electrode (4), a source electrode (5) and a drain electrode (6). The channel length L is illustrated by the double arrow.

Unless the context clearly indicates otherwise, as used herein plural forms of the terms herein are to be construed as including the singular form and vice versa.

Throughout the description and claims of this specification, the words “comprise” and “contain” and variations of the words, for example “comprising” and “comprises”, mean “including but not limited to”, and are not intended to (and do not) exclude other components.

It will be appreciated that variations to the foregoing embodiments of the invention can be made while still falling within the scope of the invention. Each feature disclosed in this specification, unless stated otherwise, may be replaced by alternative features serving the same, equivalent or similar purpose. Thus, unless stated otherwise, each feature disclosed is one example only of a generic series of equivalent or similar features.

All of the features disclosed in this specification may be combined in any combination, except combinations where at least some of such features and/or steps are mutually exclusive. In particular, the preferred features of the invention are applicable to all aspects of the invention and may be used in any combination. Likewise, features described in non-essential combinations may be used separately (not in combination).

It will be appreciated that many of the features described above, particularly of the preferred embodiments, are inventive in their own right and not just as part of an embodiment of the present invention. Independent protection may be sought for these features in addition to or alternative to any invention presently claimed.

The invention will now be described in more detail by reference to the following examples, which are illustrative only and do not limit the scope of the invention.

The following parameters are used:

μ is the charge carrier mobility

W is the length of the drain and source electrode

L is the distance of the drain and source electrode

I_{DS} is the source-drain current

Cᵢ is the capacitance per unit area of the gate dielectric

V_{G} is the gate voltage (in V)

V_{DS} is the source-drain voltage

V_{T} is the offset voltage

Unless stated otherwise, all specific values of physical parameters like the permittivity (ε), charge carrier mobility (μ), solubility parameter (δ) and viscosity (η) as given above and below refer to a temperature of 20° C. (+/−1° C.). Ratios of monomers or repeating units in polymers are given in mol %. Ratios of polymers in polymer blends are given in weight %. The molecular weight of polymers is given as weight average molecular weight M_{w} (GPC, polystyrene standard), unless stated otherwise. Formulation viscosities are obtained using an automated microviscometer (available for example from Anton Paar GmbH, Graz, Austria), which is based on the rolling/falling ball principle. A capillary is used in which a small metal ball rolls and by tilting this one way or the other the ball will descent through the liquid and can be timed. The length of time taken to pass a set distance through the liquid is proportional to the viscosity and the angle at which the tube is held at during this determines the shear rate of the measurement—which, for a Newtonian liquid, should not affect the recorded viscosity.

### Example 1

A test field effect transistor is manufactured by using a glass substrate (Corning Eagle 2000) upon which are patterned Au source and drain electrodes by evaporation though a shadow mask. Following Au source and drain evaporation the samples are cleaned in an oxygen plasma (1 KW, 500 mL/min) for 90 s. The samples are then immersed in 10 mM pentafluorobenzenethiol (Aldrich cat. no. P565-4) for 10 minutes followed by rinsing in 2-propanol and drying under a stream of compressed air.

Semiconductor formulations are made using the OSC compound 6,13-bis(triisopropylsilylethynyl)pentacene (“TIPS”, formula I1 above) blended with PTAA1 (formula II1a above, permittivity 2.9) or an inert binder resin polystyrene (PS M_{w} 1,000,000 Aldrich cat. no. 48,080-0, permittivity 2.5) (comparative example) at a 1:1 ratio by weight. For the TIPS/PTAA formulation, the semiconductor formulation is dissolved four parts into 96 parts of tetrahydronapthalene, and spin coated onto the substrate at 500 rpm for 10 s followed by 2000 rpm for 20 s. For the TIPS/PS formulation, the semiconductor formulation is dissolved two parts into 98 parts of tetrahydronapthalene, and spin coated onto the substrate at 500 rpm for 10 s followed by 2000 rpm for 60 s. To ensure complete drying the sample is placed in an oven for 20 minutes at 100° C. The insulator material (Cytop 809M, Asahi glass) is mixed 1:1 by weight with perfluorosolvent (FC43, Acros cat. no. 12377) and then spin-coated onto the semiconductor giving a thickness typically of approximately 0.5 μm. The sample is placed once more in an oven at 100° C. to evaporate solvent from the insulator. A gold gate contact is defined over the device channel area by evaporation through a shadow mask. To determine the capacitance of the insulator layer a number of devices are prepared which consisted of a non-patterned Au base layer, an insulator layer prepared in the same way as that on the FET device, and a top electrode of known geometry. The capacitance is measured using a hand-held multimeter, connected to the metal either side of the insulator. Other defining parameters of the transistor are the length of the drain and source electrodes facing each other (W=1 mm) and their distance from each other (L=varied from 110 to 7 μm).

The field effect mobility of the materials is tested using techniques described by Sirringhaus et al (Appl. Phys. Lett. 71, (26) pp 3871-3873). The voltages applied to the transistor are relative to the potential of the source electrode. In the case of a p type gate material, when a negative potential is applied to the gate, positive charge carriers (holes) are accumulated in the semiconductor on the other side of the gate dielectric. (For an n channel FET, positive voltages are applied). This is called the accumulation mode. The capacitance/area of the gate dielectric Cᵢ determines the amount of the charge thus induced. When a negative potential V_{DS} is applied to the drain, the accumulated carriers yield a source-drain current I_{DS} which depends primarily on the density of accumulated carriers and, importantly, their mobility in the source-drain channel. Geometric factors such as the drain and source electrode configuration, size and distance also affect the current. Typically a range of gate and drain voltages are scanned during the study of the device. The source-drain current is described by equation 1.

$${I}_{DS} = \frac{μ W {C}_{i}}{L} ( ( {V}_{G} - {V}_{T} ) {V}_{DS} - \frac{{V}_{DS}^{2}}{2} ) + {I}_{Ω} \qquad ( 1 )$$

where V₀ is an offset voltage and I_{Ω} is an ohmic current independent of the gate voltage and is due to the finite conductivity of the material. The other parameters have been described above.

For the electrical measurements the transistor sample is mounted in a sample holder. Microprobe connections are made to the gate, drain and source electrodes using Karl Suss PH100 miniature probe-heads. These are linked to a Hewlett-Packard 4155B parameter analyser. The drain voltage is set to −5 V and the gate voltage is scanned from +10 to −40V and back to +10V in 1 V steps, immediately after this the drain voltage is set to −40V and the gate scanned from +10V to −40V and back to +10V once more. For the V_{d} −40V scan the saturation mobility of the devices are extracted using equation 2 below.

$$μ = \frac{2 L}{W {C}_{i}} {( \frac{Δ I {d}^{\frac{1}{2}}}{Δ ( {V}_{G} - {V}_{T} )} )}^{2} \qquad ( 2 )$$

FIG. 1 shows an example graph for the TIPS/PS composition on a 100 μm channel length device. The dashed line is used to calculate the

$$( \frac{Δ I {d}^{\frac{1}{2}}}{Δ ( {V}_{G} - {V}_{T} )} )$$

part of equation 2. The capacitance, channel length and width are measured for each device.

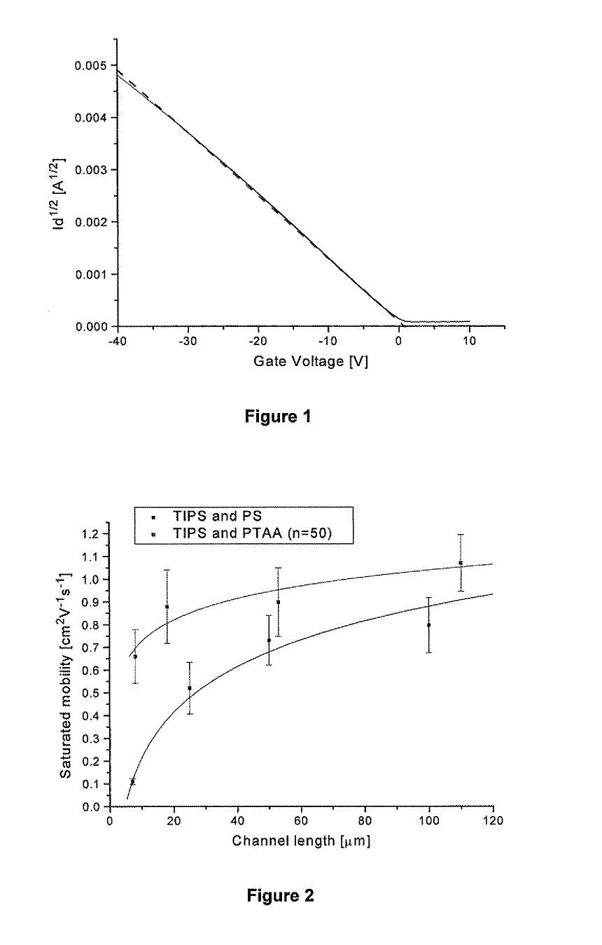

FIG. 2 shows the saturated mobilities for varying channel lengths for the two formulations—TIPS/PS and TIPS/PTAA. It can be seen that the TIPS/PTAA formulation gives high mobilities on short channel devices and therefore is preferred over the TIPS/PS formulation.

### Example 2

A test field effect transistor is manufactured using a glass substrate, upon which are patterned Au source and drain electrodes by shadow masking. The electrodes are treated for 1 minute with a 10 mM solution of pentafluorobenzenethiol (Aldrich cat. No. P565-4). A semiconductor formulation is prepared using the compound TIPS (formula I1 above) blended with PTAA1 (formula II1a above, permittivity 2.9) and Spirobifluorene (formula 6 above) in a ratio of 2:1:1 respectively by weight. The semiconductor formulation is dissolved 4 parts into 96 parts of solvent (tetrahydronapthalene), and spin coated onto the substrate and Pt/Pd electrodes at 500 rpm for 20 s followed by 2000 rpm for 20 s. To ensure complete drying the sample is placed on a hotplate for 1 minute at 100° C. followed by 30 minutes in an air oven at 100° C. A solution of the insulator material (Cytop 809M, Asahi glass) is mixed 1:1 by weight with the fluorosolvent FC43 (Acros cat. no.12377) and then spin-coated onto the semiconductor layer, giving a thickness of approximately 500 nm. The sample is placed once more in an oven at 100° C. for 20 minutes to evaporate solvent from the insulator layer. A gate contact is defined over the device channel area by evaporation of 30 nm of gold through a shadow mask. To determine the capacitance of the insulator layer a number of devices are prepared which consist of a non-patterned Au base layer, an insulator layer prepared in the same way as that on the FET device, and a top electrode of known geometry. The capacitance is measured using a hand-held multimeter, connected to the metal either side of the insulator. Other defining parameters of the transistor are the length of the drain and source electrodes facing each other (W=1 mm) and their distance from each other (L=varied from 10 to 100 μm).

The voltages applied to the transistor are relative to the potential of the source electrode. In the case of a p-type gate material, when a negative potential is applied to the gate, positive charge carriers (holes) are accumulated in the semiconductor on the other side of the gate dielectric. (For an n channel FET, positive voltages are applied). This is called the accumulation mode. The capacitance/area of the gate dielectric Cᵢ determines the amount of the charge thus induced. When a negative potential V_{DS} is applied to the drain, the accumulated carriers yield a source-drain current I_{DS} which depends primarily on the density of accumulated carriers and, importantly, their mobility in the source-drain channel. Geometric factors such as the drain and source electrode configuration, size and distance also affect the current. Typically a range of gate and drain voltages are scanned during the study of the device. The source-drain current is described by Equation 3.

$${I}_{DS} = \frac{μ W {C}_{i}}{L} ( ( {V}_{G} - {V}_{0} ) {V}_{DS} - \frac{{V}_{DS}^{2}}{2} ) + {I}_{Ω} \qquad ( 3 )$$

wherein V₀ is an offset voltage and I_{Ω} is an ohmic current independent of the gate voltage and is due to the finite conductivity of the material. The other parameters are described above.

For the electrical measurements the transistor sample is mounted in a sample holder. Microprobe connections are made to the gate, drain and source electrodes using Karl Suss PH100 miniature probe-heads. These are linked to a Hewlett-Packard 4155B parameter analyser. The drain voltage is set to −5 V and the gate voltage is scanned from +10 to −40V in 0.5 V steps. After this the drain is set to −40V and the gate once again scanned between +10V and −40V. In accumulation, when |V_{G}|>|V_{DS}| the source-drain current varies linearly with V_{G}. Thus the field effect mobility can be calculated from the gradient (S) of I_{DS} vs. V_{G} given by Equation 4.

$$S = \frac{μ W {C}_{i} {V}_{DS}}{L} \qquad ( 4 )$$

All field effect mobilities quoted below are calculated from this regime (unless stated otherwise). Where the field effect mobility varied with gate voltage, the value is taken as the highest level reached in the regime where |V_{G}|>|V_{DS}| in accumulation mode.

FIG. 4 shows the transfer characteristics (current and mobility) of a 10 micron channel length device made using this formulation. FIG. 6 is an graph of the channel length dependence of this formulation showing much less variation as the channel length shortens compared to the TIPS:PS formulation in example 1.

1. Electronic component or device comprising a gate electrode, a source electrode and a drain electrode, wherein the source and the drain electrode are separated by a specific distance (“channel length”), said component or device further comprising an organic semiconducting (OSC) material that is provided between the source and drain electrode and comprises one or more OSC compounds and an organic binder, characterized in that the channel length is ≦50 microns and the binder is a semiconducting binder.

2. Device according to claim 1, characterized in that the channel length is ≦20 microns.

3. Device according to claim 1, characterized in that the semiconducting binder is selected from polyarylamines and their copolymers, polyfluorenes and their copolymers, polyindenofluorenes and their copolymers, polyspirobifluorenes and their copolymers, polysilanes and their copolymers, polythiophenes and their copolymers, polyarylamine-butadiene copolymers.

4. Device according to claim 1, characterized in that the semiconducting binder is selected from PTAA and its copolymers, PTAA polyfluorene copolymers, polyphenyltrimethyldisilane, cis- and trans-polyindenofluorenes and their copolymers with PTAA, all having optionally alkyl or aromatic substitution.

5. Device according to claim 1, characterized in that the OSC compound is selected from formula I 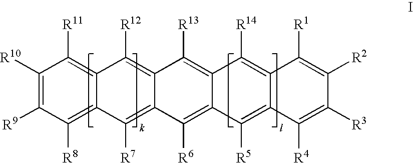
wherein
k is 0 or 1,
l is 0 or 1,
R¹⁻¹⁴ denote, in case of multiple occurrence independently of one another, identical or different groups selected from H, halogen, —CN, —NC, —NCO, —NCS, —OCN, —SCN, —C(═O)NR⁰R⁰⁰, —C(—O)X, —C(═O)R⁰, —NH₂, —NR⁰R⁰⁰, —SR⁰, —SO₃H, —SO₂R⁰, —OH, —NO₂, —CF₃, —SF₅, optionally substituted silyl, or carbyl or hydrocarbyl with 1 to 40 C atoms that is optionally substituted and optionally comprises one or more hetero atoms,
X is halogen,
R⁰ and R⁰⁰ are independently of each other H or an optionally substituted carbyl or hydrocarbyl group optionally comprising one or more hetero atoms,
optionally two or more of the substituents R¹-R¹⁴, which are located on adjacent ring positions of the polyacene, constitute a further saturated, unsaturated or aromatic ring system having 4 to 40 C atoms, which is monocyclic or polycyclic, is fused to the polyacene, is optionally intervened by one or more groups selected from —O—, —S— and —N(R⁰)—, and is optionally substituted by one or more identical or different groups R¹,
optionally one or more of the carbon atoms in the polyacene skeleton or in the rings formed by R¹⁻¹⁴ are replaced by a heteroatom selected from N, P, As, O, S, Se and Te.

6. Device according to claim 5, characterized in that in formula I R⁵, R⁷, R¹² and R¹⁴ are H, and R⁶ and R¹³ are —C≡C—SiR′R″R′″, with R′, R″ and R′″ being selected from optionally substituted C₁₋₁₀ alkyl and optionally substituted C₆₋₁₀ aryl.

7. Device according to claim 5, characterized in that in formula I at least one of R^{1- 4}and R⁸⁻¹¹ is different from H and is selected from straight-chain or branched C₁₋₆-alkyl or F, and k and l are 1.

8. Device according to claim 5, characterized in that in formula I
a) l=0, and R² and R³ together with the polyacene form a heteroaromatic ring selected from pyridine, pyrimidine, thiophene, selenophene, thiazole, thiadiazole, oxazole and oxadiazole, and/or
b) k=0, and R⁹ and R¹⁰ together with the polyacene form a heteroaromatic ring selected from pyridine, pyrimidine, thiophene, selenophene, thiazole, thiadiazole, oxazole and oxadiazole.

9. Device according to claim 1, characterized in that it is an organic field effect transistor (OFET), thin film transistor (TFT), component of integrated circuitry (IC), radio frequency identification (RFID) tag, photodetector, sensor, logic circuit, memory element, capacitor, organic photovoltaic (OPV) cell, charge injection layer, Schottky diode, photoconductor, or electrophotographic element.

10. Device according to claim 1, characterized in that it is a top gate or bottom gate OFET device.

11. Process for preparing a device according to claim 1, characterized in that it comprises the following steps:
a) mixing one or more OSC compound(s) and semiconducting binder(s) or precursors thereof, optionally with a solvent or solvent mixture,
b) applying the mixture or the solvent(s) containing the OSC compound(s) and binder(s) to a substrate; and optionally evaporating the solvent(s) to form a solid OSC layer,
c) optionally removing the solid OSC layer from the substrate or the substrate from the solid layer
wherein the OSC compound(s) is selected from Formula I 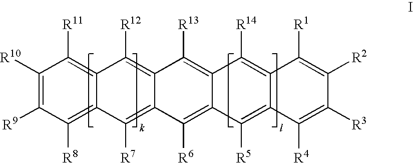
wherein
k is 0 or 1,
l is 0 or 1,
R¹⁻¹⁴ denote, in case of multiple occurrence independently of one another, identical or different groups selected from H, halogen, —CN, —NC, —NCO, —NCS, —OCN, —SCN, —C(═O)NR⁰R⁰⁰, —C(═O)X, —C(═O)R⁰, —NH₂, —NR⁰R⁰⁰, —SH, —SR⁰, —SO₃H, —OH, —NO₂, —CF₃, —SF₅, optionally substituted silyl, or carbyl or hydrocarbyl with 1 to 40 C atoms that is optionally substituted and optionally comprises one or more hetero atoms,
X is halogen,
R⁰ and R⁰⁰ are independently of each other H or an optionally substituted carbyl or hydrocarbyl group optionally comprising one or more hetero atoms,
optionally two or more of the substituents R¹-R¹⁴, which are located on adjacent ring positions of the polyacene, constitute a further saturated, unsaturated or aromatic ring system having 4 to 40 C atoms, which is monocyclic or polycyclic, is fused to the polyacene, is optionally intervened by one or more groups selected from —O—, —S— and —N(R⁰)—, and is optionally substituted by one or more identical or different groups R¹,
optionally one or more of the carbon atoms in the polyacene skeleton or in the rings formed by R¹⁻¹⁴ are replaced by a heteroatom selected from N, P, As, O, S, Se and Te
wherein the semiconducting binder is selected from
polyarylamines,
polyfluorenes,
polyindenofluorenes,
polyspirobifluorenes,
polysilanes,
polythiophenes,
copolymers of one or more of the aforementioned polymers,
polyarylamine-butadiene copolymers,
PTAA and its copolymers, having optionally alkyl or aromatic substitution,
copolymers of polyfluorenes with PTAA, having optionally alkyl or aromatic substitution,
copolymers of polysilanes with PTAA, having optionally alkyl or aromatic substitution,
polyphenyltrimethyldisilane, having optionally alkyl or aromatic substitution,
copolymers of polyphenyltrimethyldisilane with PTAA, having optionally alkyl or aromatic substitution,
cis- and trans-polyindenofluorenes, having optionally alkyl or aromatic substitution, and
copolymers of cis- and trans-polyindenofluorenes with PTAA, having optionally alkyl or aromatic substitution.
